(19) United States
(12) Patent Application Publication
(10) Pub. No.: US 2025/0040097 A1
(43) Pub. Date: Jan. 30, 2025

(54) THERMAL MANAGEMENT DEVICE WITH COMPRISING AN ARRAY OF THERMALLY CONDUCTIVE PIECES

(71) Applicant: MOMENTIVE PERFORMANCE MATERIALS QUARTZ, INC., Strongsville, OH (US)

(72) Inventors: Anand Murugaiah, Brunswick, OH (US); Matthew Peter Gallaugher, Middleburg Heights, OH (US); Sudarshan Natarajan, solon, OH (US); Dhavalkumar Patel, Strongsville, OH (US); David Sabens, Solon, OH (US)

(21) Appl. No.: 18/750,229

(22) Filed: Jun. 21, 2024

Related U.S. Application Data
(60) Provisional application No. 63/528,695, filed on Jul. 25, 2023.

(51) Int. Cl. H05K 7/20

(52) U.S. Cl. CPC H05K 7/2039

(57) ABSTRACT

A thermal management device is provided. The thermal management device includes a first substrate, a second substrate, and a thermal spreader layer. The second substrate is arranged over the first substrate, and the thermal spreader layer is arranged between the first substrate and the second substrate. The thermal spreader layer includes a first thermally conductive piece having a first edge and a second thermally conductive piece having a first edge. The first edge of the first thermally conductive piece is disposed adjacent to the first edge of the second thermally conductive piece.

### RELATED APPLICATIONS

This application claims the benefit of and priority to U.S. Provisional Application No. 63/528,695 filed on Jul. 25, 2023, which is hereby incorporated herein by reference in its entirety.

### TECHNICAL FIELD

In general, the present disclosure relates to a thermal management device. In particular, the present disclosure relates to thermal management device that includes a thermally conductive core having a plurality of thermally conductive pieces that are arranged in close proximity to one another to promote more uniform thermal conductivity across the thermally conductive core.

### BACKGROUND OF THE INVENTION

In semiconductor processing, having uniform heat applied to the wafer during various processing such as epitaxy is highly desirable. Additionally, heat may be undesirably generated in electronics and electrical systems, including semiconductor applications and systems comprising processors, circuits, displays, power storage units, and the like, for example. Thermal management of these electronics and electrical systems is important to ensure proper operation, safety, longevity, and undiminished performance over the lifetime of the systems.

### SUMMARY OF THE INVENTION

The following presents a summary of this disclosure to provide a basic understanding of some aspects. This summary is intended to neither identify key or critical elements nor define any limitations of embodiments or claims. Furthermore, this summary may provide a simplified overview of some aspects that may be described in greater detail in other portions of this disclosure.

In one aspect, provided is a thermal management device having a thermal spreader layer disposed between two substrates. The thermal spreader layer includes a plurality of thermally conductive pieces, where adjacent pieces are oriented such that an edge of one piece is closely positioned relative to the edge of an adjacent piece. The edges of adjacent pieces are closely positioned such that they may be considered thermally coupled to promote uniform heat transfer in the planar direction of the thermal spreader layer. The edges can be provided with a shape as desired to form a selected closely spaced/mating relationship. The edges could be, for example, straight, beveled, curved, stepped, regular, or irregular shaped.

In one embodiment, the edges of adjacent pieces are in contact with one another. In one embodiment, the edges of adjacent pieces are separated by a bonding material joining the pieces together.

In one embodiment, the edges of adjacent pieces of the thermal spreader layer are beveled at complimentary angles.

In another embodiment, the edges of adjacent pieces of the thermal spreader layer have ship laps such that the pieces overlap.

In yet another embodiment, the edges of the adjacent pieces of the thermal spreader layer comprises beveled edges and a ship laps.

In another aspect, provided is a method of making a thermal management device, including arranging and securing pieces of a thermal spreader layer between two substrates.

These and other aspects will be evident when viewed in light of the drawings, detailed description, and appended claims.

### BRIEF DESCRIPTION OF THE DRAWINGS

Various non-limiting embodiments may take physical form in certain parts and arrangements of parts, which will be described in detail in the specification and illustrated in the accompanying drawings which form a part hereof, and wherein:

FIG. 1 illustrates a perspective view of a cylindrical thermal leveler in accordance with an embodiment of the technology.

FIG. 2 illustrates a top view of the thermal leveler of FIG. 1.

FIGS. 3A and 3B illustrate cross-sectional views of some embodiments of the thermal leveler illustrated in FIGS. 1 and 2.

FIG. 4A illustrates a cross-sectional view of another embodiment of a thermal leveler in accordance with an embodiment of the technology.

FIG. 4B illustrates a cross-sectional view of another embodiment of a thermal leveler in accordance with an embodiment of the technology.

FIGS. 5A and 5B illustrate various views of another embodiment of a thermal leveler comprising support vias in accordance with aspects of the technology.

FIGS. 6A and 6B illustrate various views of some embodiments of thermal leveler comprising support vias and a thermal control structure integrated with two substrates.

FIGS. 7A, 7B, and 7C illustrate additional cross-sectional views of other embodiments of a thermal spreader layer.

FIG. 8 illustrates a cross-sectional view of some embodiments of a thermal leveler comprising two rows of the thermal spreader layer as described further herein.

FIGS. 9A, 9B, 9C, 9D, and 9E illustrate top view embodiments of multiple thermally conductive tiling patterns for a thermal spreader layer in accordance with some embodiments of the technology.

FIGS. 10A and 10B illustrate top view embodiments of thermally conductive tiling patterns with varying structural and gaps present for separate zone control in accordance with some embodiments of the technology.

FIG. 11 illustrates a perspective view of a substrate in accordance with an embodiment of the technology.

FIG. 12 illustrates a cross-sectional view of some embodiments of a thermal spreader layer piece on the substrate of FIG. 10.

FIGS. 13A and 13B illustrate cross-sectional views of some other embodiments of a thermal spreader layer arranged within a cavity of a substrate.

FIG. 14 illustrates temperature profiles showing the heat spreading properties of some embodiments of a thermal leveler as described herein in view of control thermal levelers.

FIGS. 15A and 15B illustrate additional temperature profiles showing the heat spreading properties of some other embodiments of a thermal leveler as described herein in view of a control thermal leveler.

### DETAILED DESCRIPTION OF THE INVENTION

Thermal levelers or spreaders employing a thermally conductive core material (e.g., thermal pyrolytic graphite, diamond, etc.) are used in various heat dissipating, leveling, spreading, and focusing applications along with a heater or cooler. The goal of using this thermal spreader layer is to achieve a desired temperature profile or desired thermal transport utilizing the enhanced thermal conductivity of the thermal spreader layer. For structures using thermal pyrolytic graphite, for example, the thermal spreader layer can be in the form of naked thermal pyrolytic graphite or can be in an encapsulated form, i.e., thermal pyrolytic graphite encapsulated by a metal, semimetal, ceramic material, polymers, alloys, or combinations thereof. Examples of an encapsulating material include aluminum and aluminum alloys, copper, stainless steels, nickel and nickel alloys, silicon, aluminum nitride, aluminum oxide, tungsten-copper, molybdenum-copper, copper and copper alloys, graphite, epoxies, acrylates, and polyolefins.

For applications in the semiconductor equipment industry, precise control of the thermal profile of the thermal leveler is desired. In most cases, achieving high temperature uniformity on an object supported by the thermal leveler is the goal. Direct control of the interfacial thermal resistance between the high thermal conductivity material and the corresponding substrate material, as well as the interfacial thermal resistance between individual pieces of thermal pyrolytic graphite can significantly enhance the performance of the thermal leveler and improve temperature uniformity.

Larger components may require the use of multiple thermal pyrolytic graphite pieces to provide the desired coverage. In larger structures, the thermal pyrolytic graphite pieces are typically separated by a wall or a web of the lower thermal conductivity substrate material. The wall and/or webbing of substrate functions as a structural member for the device, but also leads to impaired heat flow between the thermal pyrolytic graphite pieces. This may result in temperature gradients and fluctuations in the thermal profile across the leveler.

Embodiments of the disclosure are directed towards methods and systems that relate to a thermal management device having a thermal spreader layer disposed between two substrates. The thermal spreader layer includes a plurality of thermally conductive pieces or tiles, where adjacent pieces are oriented such that an edge of one piece is closely positioned relative to the edge of an adjacent piece. The edges of adjacent pieces are closely positioned such that they function as if thermally coupled to promote uniform heat transfer in the planar direction of the thermal spreader layer. The edges can be provided with a shape as desired to provide a selected closely spaced/mating relationship. The edges could be, for example, straight, beveled, curved, stepped, regular, or irregular shaped.

As used herein the terms “thermal management device,” “thermal leveler,” and “thermal spreader,” may be used interchangeably. Generally, such devices are configured with a thermally conductive material adapted to transfer heat across the device in at least one of the in-plane or through plane directions of the material.

With reference to the drawings, like reference numerals designate identical or corresponding parts throughout the several views. The inclusion of like elements in different views, however, does not mean a given embodiment necessarily includes such elements or that all embodiments include such elements. The examples and figures are illustrative only and not meant to be limiting of the claimed subject matter.

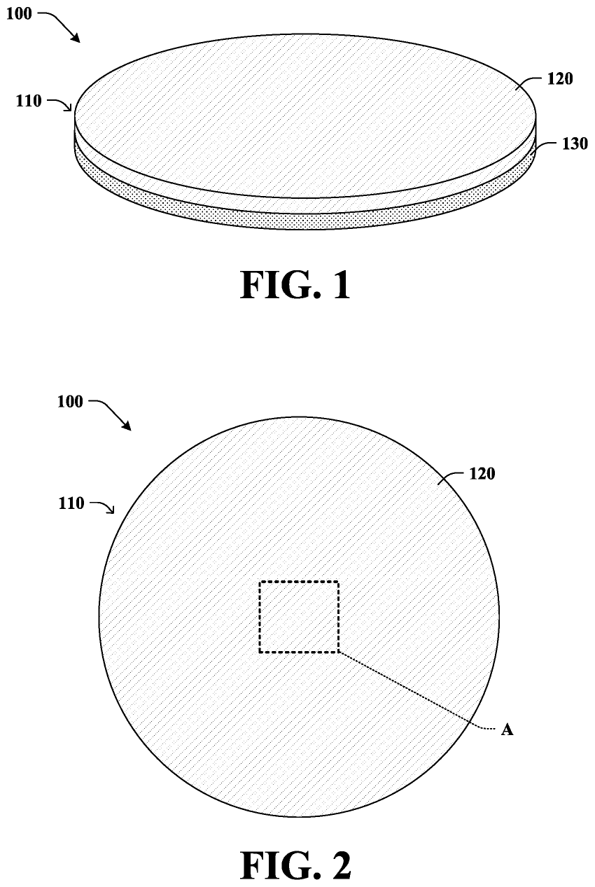

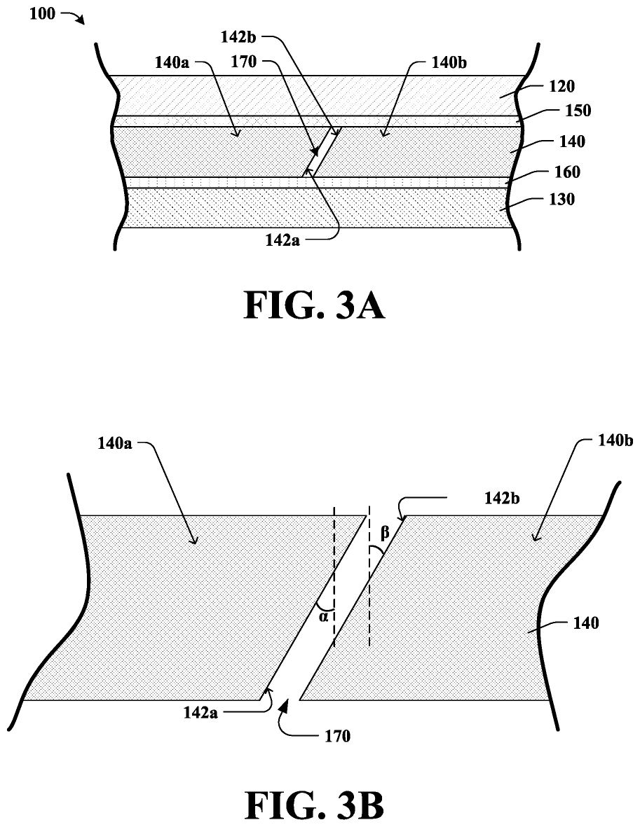

Turning now to FIGS. 1, 2, 3A, and 3B, an embodiment of a thermal leveler 100 is illustrated. In particular, FIG. 1 illustrates a perspective view of the thermal leveler 100; FIG. 2 illustrates a top-view of the thermal leveler 100; FIG. 3A illustrates a magnified, cross-sectional view of some embodiments of the thermal leveler 100; and FIG. 3B illustrates an even more magnified view of certain components from FIG. 3A. The cross-sectional view of FIG. 3A may correspond to box A of FIG. 2. It will be appreciated that the design and arrangement of components shown in FIGS. 3A and 3B may vary amongst different embodiments of the thermal leveler 100 described herein.

As shown in FIGS. 1-3B, the thermal leveler 100 includes a body 110 formed by a first substrate 120 stacked with a second substrate 130. A thermal spreader layer 140 is disposed within the body 110. The thermal spreader layer 140 may be completely encapsulated within the body 110 such that the thermal spreader layer 140 is not visible in FIGS. 1 and 2. It will be appreciated that other embodiments, the thermal spreader layer 140 is disposed between the first and the second substrates 120, 130, but the thermal spreader layer 140 is not surrounded or is only partially covered by the substrates 120, 130. In some other embodiments, the first and second substrates 120, 130 could be constructed of a plurality of layers through stack forging or additive manufacturing.

As best seen in FIGS. 3A and 3B, the thermal spreader layer 140 is provided by a plurality of thermally conductive pieces. In some embodiments, the thermal spreader layer 140 includes, for example, a graphite material, aluminum nitride, aluminum, copper, molybdenum, diamond, a combination of two or more thereof, and the like. In some embodiments where the thermal spreader layer 140 includes a graphite material, the graphite material may be selected from pyrolytic graphite or thermal pyrolytic graphite. Thermal pyrolytic graphite is a unique graphite material having crystallites of considerable size, the crystallites being highly aligned or oriented with respect to each other and having well-ordered carbon layers or a high degree of preferred crystallite orientation. Thermal pyrolytic graphite may be used interchangeably with “highly oriented pyrolytic graphite” (“HOPG”), or compression annealed pyrolytic graphite (“CAPG”). Thermal pyrolytic graphite is extremely thermally conductive with an in-plane (a-b direction) thermal conductivity greater than 1000 W/m-K, while the thermal conductivity in the out-of-plane (2-direction) is in the range of 5 to 30 W/m-K. The thermal spreader layer 140 having thermal pyrolytic graphite can have an in-plane thermal conductivity greater than 1000 W/m-K; greater than 1100 W/m-K, greater than 1200 W/m-K, greater than 1300 W/m-K, greater than 1400 W/m-K, even greater than 1500 W/m-K. In one embodiment, the high thermal conductivity insert has an in-plane thermal conductivity of from about 1000 W/m-K to about 1500 W/m-K. The thermal spreader layer 140 may have a higher thermal conductivity than that of the first and second substrates 120, 130.

Thermal pyrolytic graphite is available, for example, from Momentive Performance Materials Quartz, Inc. In one embodiment, thermal pyrolytic graphite is formed as described in U.S. Pat. No. 5,863,467 which is hereby incorporated herein by reference in its entirety. The configuration of the thermal leveler 100 is not particularly limited and can be selected as desired for a particular application or end use. In particular, the configuration of the thermal leveler 100 will be chosen to provide a desired thermal profile. The orientation and number of thermal pyrolytic graphite sheets and pieces in the thermal leveler 100 is not particularly limited. The number, orientation, and position of the sheets and pieces can be selected as desired to provide a particular thermal profile.

For an example that contains two thermal pyrolytic graphite tiles, the thermal spreader layer 140 includes a first thermally conductive piece 140a and a second thermally conductive piece 140b. The first and second thermally conductive pieces 140a, 140b are disposed in the thermal leveler 100 such that an inner edge 142a of first piece 140a is in close proximity to an inner edge 142b of the second piece 140b. In some embodiments, a first bonding layer 150 is further arranged between the first substrate 120 and the thermal spreader layer 140, and a second bonding layer 160 is further arranged between the substrate 130 and the thermal spreader layer 140. The bonding layers 150, 160 may provide diffusion prevention, bonding, thermal dissipation, or other similar functions between the thermal spreader layer 140 and substrates 120, 130.

FIG. 3B corresponds to the embodiment of FIG. 3A and illustrates a magnified view of the first thermally conductive piece 140a and the second thermally conductive piece 140b. In some embodiments, the first and second thermally conductive pieces 140a, 140b are provided with beveled edges. The edge 142a of piece 140a has an angle α relative to a vertical axis, and the edge 142b of piece 140b has an angle β relative to a vertical axis. The vertical axes are normal to upper surfaces of the thermal leveler 100. The angles α and β are each independently greater than 0° and less than 90°. In one embodiment, angles α and β are complimentary angles having a sum of 90°. In one embodiment, angles α and β are each independently equal to, for example, 10°, 15°, 30° 45°, 60°, 75°, or 80°. In one embodiment, angles α and β are each independently equal to, for example, 10°, 15°, 30° 45°, 60°, 75°, or 80°, where α and β are complimentary angles.

By providing beveled edges 142a, 142b, the adjacent pieces 140a, 140b can essentially mate with one another. The beveled edges 142a, 142b have been found to provide good thermal transfer or communication across adjacent thermally conductive pieces 140a, 140b in the thermal spreader layer 140. Additionally, it has been found that the use of beveled edges 142a, 142b for adjacent thermally conductive pieces 140a, 140b provides a joint that exhibits good thermal transfer even if there is some in plane movement of the adjacent pieces. For example, some minor shifting between adjacent thermally conductive pieces 140a, 140b relative to one another may occur during manufacturing of the thermal leveler 100 and/or during temperature and/or mechanical stresses within the thermal leveler 100 when in use for its intended application. Even with such shifting, the thermal spreader layer 140 may still have good thermal transfer between adjacent thermally conductive pieces (e.g., 140a, 140b in FIG. 3A).

The thermally conductive pieces 140a, 140b with the beveled edges 142a, 142b can be positioned within the thermal leveler 100 such that there is a small gap 170 between adjacent pieces 140a, 140b, or can be provided such that the edges 142a, 142b of adjacent pieces 140a, 140b are in contact with one another. In one embodiment, the gap 170 has a width between the edges 142a, 142b of adjacent pieces 140a, 140b in a range of between, for example, about 0.001″ to about 0.100″, from about 0.050″ to about 0.05″, or from about 0.0025″ to about 0.01″. Such a gap 170 can be filled with a bonding material or by the thermally conductive tiles 140a, 140b in close contact with each other. In some other embodiments, the gap 170 could be left as an airgap to provide thermal isolation between different areas or zones of the thermal leveler 100 that surround the gap 170. The gap 170 may also provide the space for the adjacent pieces 140a, 140b to slightly shift during manufacturing and/or temperature fluctuations without damaging the thermal spreader layer 140.

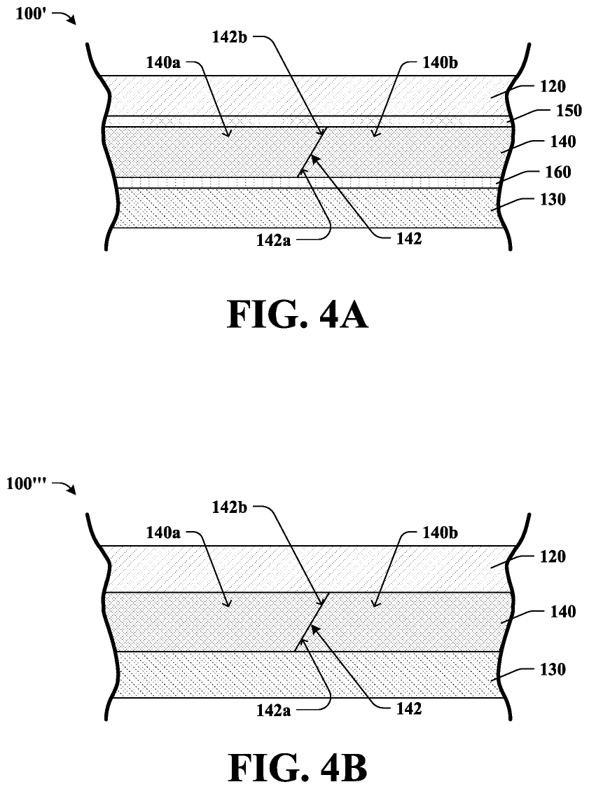

Turning additionally to FIG. 4A, another partial cross-section of a thermal leveler 100′ is illustrated. The thermal leveler 100′ of FIG. 4A is the same as the thermal leveler 100 of FIGS. 1-3B except that in FIG. 4A, the thermally conductive pieces 140a and 140b are in contact with one another at an interface 142. Thus, the thermal leveler 100′ of FIG. 4A does not include any gap (e.g., 170 in FIG. 3B) between the thermally conductive pieces 140a, 140b.

Turning additionally to FIG. 4B, another partial cross-section of a thermal leveler 100″″ is illustrated. The thermal leveler 100′″ of FIG. 4B is the same as leveler 100′ in FIG. 4A except leveler 100′″ does not include bonding layers (e.g., 150 or 160 of FIG. 4A) between the thermally conductive pieces 140a, 140b and the substrates 120, 130.

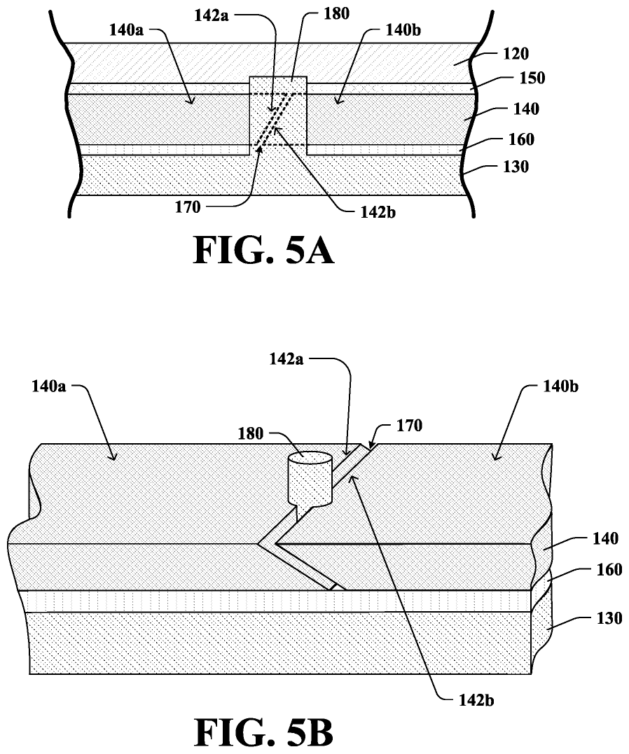

Turning additionally to FIG. 5A, in some embodiments, the thermal leveler 100 further includes one or more support vias 180. The support via 180 may extend through a portion of the thermal spreader layer 140. In FIG. 5A, the edges 142a, 142b are illustrated with dotted lines because the cross-sectional view of FIG. 5A extends through the support via 180; it will be appreciated that the edges 142a, 142b would not actually be visible in the cross-sectional view of FIG. 5A.

In some embodiments, as shown in FIG. 5A, the support via 180 is a protrusion from the second substrate 130 and is continuously formed with the second substrate 130. In some other embodiments, the support via 180 is a protrusion from the first substrate 120 or is a separate thermally conductive component arranged between the first and second substrates 120, 130. The support via 180 may have a thermal conductivity lower than that of the thermal spreader layer 140. In some embodiments, the support via 180 extending from the second substrate 130 aligns with a recess of the first substrate 120. In some other embodiments, the support via 180 contacts a bottommost surface of the first substrate 120. The support via 180 may also fully extend through bonding layers 150, 160, if present. In some embodiments, one of the bonding layers 150, 160 may coat outer surfaces of the support via 180 to prevent the support via 180 from directly contacting the thermal spreader layer 140. For example, in some embodiments, surfaces of the support via 180 that face the thermal spreader layer 140 may include the bonding layers 150, 160, whereas surfaces of the support via 180 that face one or both of the substrates 120, 130 do not include the bonding layers 150, 160. This way, diffusion between the support vias 180 and the thermal spreader layer 140 is mitigated by the present bonding layer(s) 150, 160, while bonding can still occur between the support vias 180 and an opposing substrate(s) 120, 130.

In some embodiments, the support via 180 is bonded to the first substrate 120, whereas in some other embodiments, the support via 180 contacts or is substantially nearby a surface of the first substrate 120 to promote heat transfer between the first substrate 120 and the support via 180. In some embodiments, the support via 180 is bonded to the first and/or second substrate 120, 130 at the same time that the first and second substrates 120, 130 are bonded to one another to encapsulate the thermal spreader layer 140. The support via 180 may provide structural support to the thermal leveler 100 and/or may assist with thermal distribution throughout the thermal leveler 100.

In some embodiments, several support vias 180 may be arranged throughout the thermal leveler 100. The support vias 180 function are to mechanically join the pieces 140a, 140b of the thermal spreader layer 140, and can be bonded to the opposing substrates 120, 130 through a binding layer or through direct bonding with the opposing substrate 120, 130 (for example, but not limited to diffusion bonding, welding, etc.). In an alternative embodiment, the support vias 180 may include the same material as the thermal spreader layer 140 and/or include an additional insert that has the same material as the thermal spreader layer 140 to connect the pieces 140a, 140b to one another. Using a support via 180 made from the same material as the thermal spreader layer 140 provides the benefit of having a similar thermal conductivity profile as the thermal spreader layer 140 to improve temperature uniformity in the thermal leveler 100.

FIG. 5B illustrates a perspective view of some embodiments of at least the first thermally conductive piece 140a and the second thermally conductive piece 140b. As shown in FIG. 5B, in some embodiments, the support via 180 extends through the beveled first and second edges 142a, 142b of the pieces 140a, 140b. Such arrangements can assist in securing and stabilizing the first thermally conductive piece 140a with the second thermally conductive piece 140b. In some other embodiments, the support via 180 extends through an inner portion of the thermally conductive piece 140a, 140b such that one support via 180 extends through one thermally conductive piece 140a or 140b. In some embodiments where the support via 180 extends through two thermally conductive pieces 140a, 140b as shown in FIGS. 5A and 5B, the adjacent pieces 140a, 140b mate to form a circle (or some other shape reflective of the support via 180 structure) around the support via 180. When several support vias 180 extend through the thermal spreader layer 140, the distribution of support vias 180 may vary.

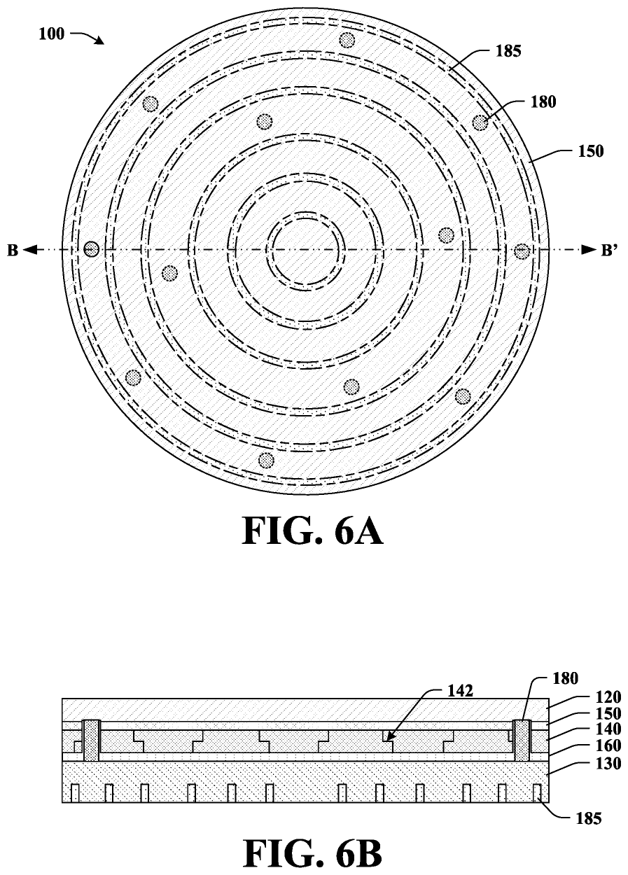

FIG. 6A illustrates a top view of some embodiments of the distribution of the support vias 180 throughout the thermal leveler 100. In some embodiments, the thermal leveler 100 includes a thermal control structure 185 which may comprise, for example, a heating coil, a cooling structure (e.g., gas lines, water lines), or some other thermal management device. The thermal control structure 185 may be arranged on or integrated with one of the first and/or second substrates 120, 130. In some embodiments, the thermal control structure 185 has a pattern to distribute heat and/or cooling air or water through the thermal leveler 100. In FIG. 6A, the thermal control structure 185 and the support vias 180 are outlined with hashed lines; it will be appreciated that the thermal control structure 185 and the support vias 180 are covered by, for example, the first substrate 120 from the top view of FIG. 6A. In some embodiments, when the thermal leveler 100 is manufactured to include the thermal control structure 185, the support via(s) 180, if present, is preferably designed to not directly overlie portions of the thermal control structure 185 to improve temperature uniformity of the thermal leveler 100. When the support vias 180 do not directly overlie portions of the thermal control structure 185, the temperature uniformity of the thermal leveler 100 is improved. In some other embodiments, due to design constraints and/or due to varying heating zone specifications, one or more of the support vias 180 may be partially or fully aligned/overlapped the thermal control structure 185 in the vertical direction.

FIG. 6B illustrates some embodiments of a cross-sectional view of the thermal leveler 100 corresponding to cross-section line BB′ of FIG. 6A. Because the support vias 180 do not directly align or overlap with the thermal control structure 185 in the vertical direction, the thermal control structure 185 may directly align or overlap with the thermal spreader layer 140 in the vertical direction. In other embodiments where there is full or partial overlap of the support vias 180 and the thermal control structure 185, no part or only some part of the thermal control structure 185 directly aligns/overlaps the thermal spreader layer 140 in the vertical direction.

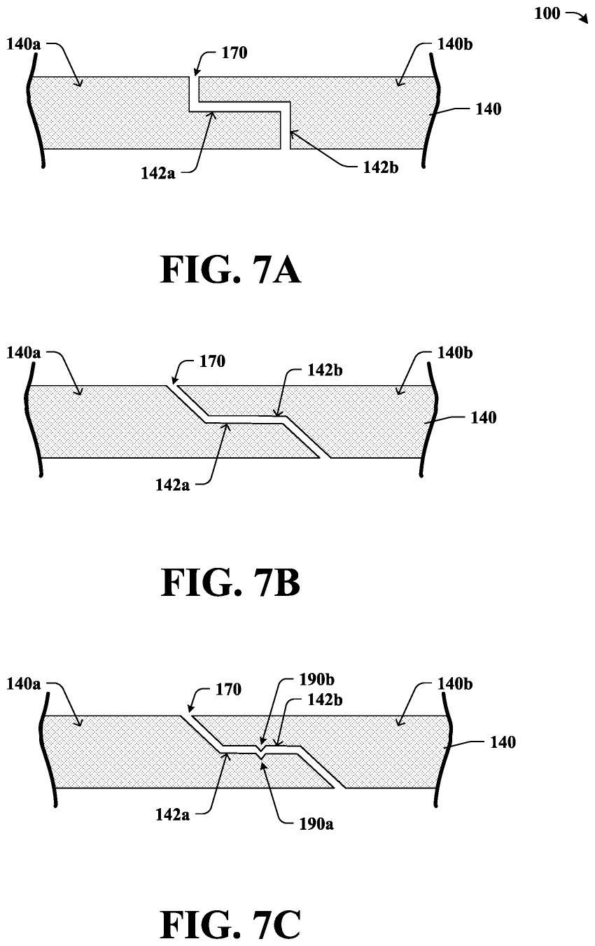

Turning now to FIGS. 7A, 7B, and 7C, some alternative embodiments of the profile of adjacent thermally conductive pieces 140a, 140b are provided. The edges 142a, 142b of adjacent thermally conductive pieces 140a, 140b can be provided with a shape as desired to provide a selected close-fitting relationship with at least some direct overlap in the vertical direction or direct contact with one another. In embodiments, the edges 142a, 142b can be straight, beveled (as described above with respect to FIGS. 3A-5B), one or more steps or ridges, and even more complex geometries if desired. The edges 142a, 142b can be provided with recesses or grooves of a desired configuration to promote a close fit of the edges with little or no gap (e.g., 170 of FIG. 3A) between the edges 142a, 142b.

FIGS. 7A-7C show some non-limiting examples of edge configurations form thermally conductive pieces other than a simple straight edge or beveled edge. The edge contours or grooves shown in FIGS. 7A-7C may be referred to as a shiplap joint. The shiplap joint can be simple or more complex as may be desired. For example, the shiplap configuration can be, but is not limited to, a simple ship lap, a ship lap with a beveled edge, and a ship lap with a beveled edge and a “spike” for greater lateral strength.

As shown in FIG. 7A, in some embodiments, the thermally conductive pieces 140a, 140b are provided with edges 142a and 142b, respectively, having a simple shiplap configuration defined by vertical and horizontal sidewalls a configured to mate with one another. For example, in FIG. 7A, each edge 142a, 142b comprises a horizontal sidewall connected to two vertical sidewalls. Each opposing edge 142a, 142b is configured to overlap and mate with one another.

As shown in FIG. 7B, in some embodiments, the thermally conductive pieces 140a and 140b have edges 142a and 142b, respectively, with a more complex shiplap groove with beveled sidewalls and horizontal sidewalls when compared to the shiplap arrangement in FIG. 7A having substantially horizontal and vertical sidewalls. For example, in FIG. 7B, each edge 142a, 142b includes a horizontal sidewall connected to two angled or beveled sidewalls. Each opposing edge 142a, 142b is configured to overlap and mate with one another.

As shown in FIG. 7C, in some embodiments, the thermally conductive pieces 140a, 140b have a shiplap groove similar to the groove of FIG. 7B except that the embodiment in FIG. 7C includes additional features to promote mating or close contact of the thermally conductive pieces 140a, 140b. For example, in FIG. 7C, the edge 142a of the first piece 140a includes a recess 190a, while the edge 142b of the second piece 140b includes a projection 190b. The recess 190a is configured to receive and mate with the projection 190b. While the recess 190a and the projection 190b are illustrated on horizontal sidewalls of the edges 142a, 142b in FIG. 7C, it will be appreciated that these mating features 190a, 190b may be arranged on other sidewalls of the edges 142a, 142b.

The embodiments of FIGS. 7A-7C are merely examples of potential embodiments of the edge configurations and other configurations of different dimensions, sizes, and complexities are within the scope of the present technology. For example, it will be appreciated that other mating features may be implemented at the edges 142a, 142b of the thermally conductive pieces 140a, 140b for close mating and favorable thermal dissipation through the thermal spreader layer 140. Additionally, the number and shape of the thermally conductive pieces 140a, 140b is not particularly limited and can be selected as desired for a particular application or intended use.

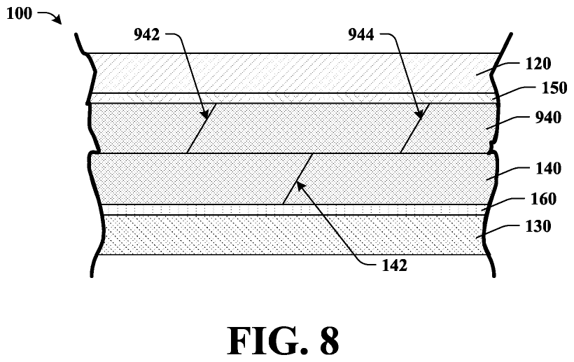

FIG. 8 illustrates another embodiment of a thermal leveler 100, which may include several thermal spreader layers 140. In some embodiments, for example, a second thermal spreader layer 940 is arranged over the thermal spreader layer 140. In some embodiments, the second thermal spreader layer 940 includes several thermally conductive pieces and includes at least a first interface 942 and a second interface 944. The first interface 942 and the second interface 944 may not directly overlie the interface 142 in the underlying thermal spreader layer 140 to improve thermal uniformity throughout the thermal spreader layers 140, 940.

While not shown in FIG. 8, in some embodiments, additional bonding layers, air gaps, insulating layers, encapsulating material matching 120 or 130, or the like may be present between adjacent pieces within each thermal spreader layer 140, 940 or between each thermal spreader layer 140, 940. Further, more than two thermal spreader layers 140, 940 may be present between the first and second substrates 120, 130.

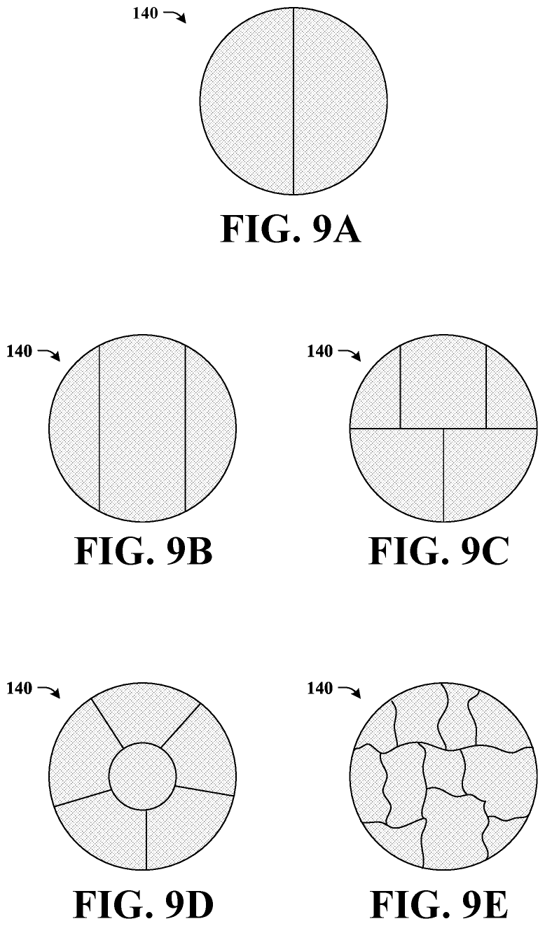

Turning now to FIGS. 9A, 9B, 9C, 9D, and 9E, show top views of various embodiments of the thermal spreader layer 140 having different tiling arrangements of thermally conductive pieces. various top views of the thermal spreader layer 140 are shown. For example, where more than two thermally conductive pieces 140a, 140b are employed, the edges of a given piece can be provided to fit with different geometries. Examples of tiling arrangements include, but are not limited to, standard linear tiling (FIGS. 9A and 9B), offset tiling so the straight edges do not run through the entire tile arrangement (FIG. 9C), a mix of shapes (such as, but not limited to, a central circular tile with outer curved pieces seen in FIG. 9D), or random irregular shapes such as a “jig-saw puzzle” arrangement (FIG. 9E). It will be appreciated that the configurations or shapes of the edges are not particularly limited for the different tiling arrangements. While the thermal spreader layers 140 of FIGS. 9A-9E show each piece in direct contact with one another, it will be appreciated that one or more gaps (e.g., 170 of FIG. 3A), support vias (e.g., 180 of FIG. 5A), or other feature such as a bonding structure may be present at the interfaces between pieces.

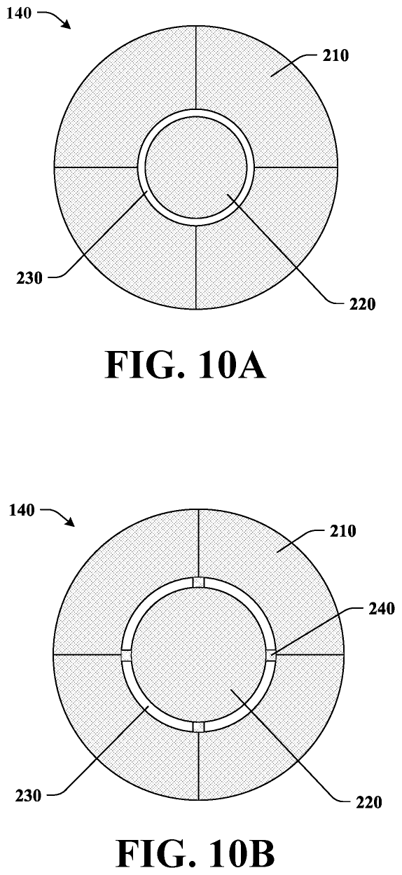

For example, as shown in FIGS. 10A and 10B, an extension or insert of the substrate material can be disposed between two or more regions of high thermal conductivity material, producing separate zones of uniform temperature. In other examples, an air gap or an insert of another material having lower thermal conductivity may be utilized to form the two or more regions. For example, the embodiments shown in FIGS. 10A and 10B show various configurations of a thermal spreader layer 140 that would have separate high thermal conductivity material in two separate zones (zones 210 and 220) for a two-zone semiconductor pedestal heater having a first zone, separated by a rim 230 of lower thermal conductivity substrate material (or a gap) shown in FIG. 10A, or partial rim 230 of lower thermal conductivity with gaps 240 in between shown in FIG. 10B. Each zone 210, 220 may include a single or several thermally conductive pieces.

Turning back to the thermal leveler 100 illustrated in FIGS. 1-3B, each component of the leveler 100 may include materials that are thermally and structurally compatible with one another and that may provide desired properties for the intended use of the thermal leveler 100. For example, the various interfaces between the thermal spreader layer 140, the bonding layers 150, 160, and the substrates 120, 130 are configured to provide a thermal leveler 100 having enhanced thermal management control, and/or reduced undesirable diffusion between the aforementioned layers, and/or enhanced bonding strength of materials and layers, and/or comparable thermal expansion coefficient (CTE) between the materials and layers.

In some embodiments, the first and second substrates 120, 130 include the same or different materials. For example, the first and second substrates 120, 130 may each include graphite, metal, semimetals, alloys, ceramics, glass, quartz, a polymer, or combinations thereof. In some embodiments, the first and second substrates 120, 130 include titanium, nickel, chromium, copper, aluminum, 6061 aluminum, stainless steel, tungsten, molybdenum, iron, gold, beryllium, carbon steels, tin, silver, gold, beryllium, alloys or composites thereof, and oxides or nitrides thereof (e.g., aluminum nitride, aluminum oxide, etc.). Suitable examples of ceramic materials that may be used for the first and second substrates 120, 130 include metal carbides (e.g., silicon carbide), metal nitrides (e.g., silicon nitride, aluminum nitride, boron nitride), silicon, and the like.

In one embodiment, the material of the substrates 120, 130 may be selected from a material commonly used in heater or cooling pedestals for semiconductor processing. In one embodiment, the substrates 120, 130 and the body 110 is formed from a material that matches the composition or material of a heater or cooling pedestal upon which the thermal leveler 100 will be used for processing. It is understood that the above-mentioned list is not a limitation and that the substrates 120, 130 may be of a different material having a lower thermal conductivity relative to the thermal conductivity of the thermal spreader layer 140.

In some embodiments, the thermal spreader layer 140 includes, for example, a graphite material, aluminum nitride, aluminum, copper, molybdenum, diamond, a combination of two or more thereof, and the like. The thermal spreader layer 140 may have a higher thermal conductivity than that of the first and second substrates 120, 130.

In some embodiments, when the thermal spreader layer 140 includes carbon (such as thermal pyrolytic graphite), the bonding layers 150, 160 may include a carbide-forming metal or material to act as a carbon diffusion barrier between the thermal spreader layer 140 and the substrates 120, 130. For example, when the substrates 120, 130 include iron and chromium, carbon diffusion between the carbon-containing thermal spreader layer 140 and the iron and chromium containing substrates 120, 130 should be reduced to maintain the structure and thus, the corrosion resistance, of the substrates 120, 130. In some embodiments, for example, the first and second substrates 120, 130 may include stainless steel and/or nickel alloys, which may experience carbon diffusion, but which also are resistant to degradation by chemicals used in manufacturing processes such as fluorine used in in-situ cleaning processes. In some embodiments, the bonding layers 150, 160 include, for example, titanium, zirconium, chromium, hafnium, aluminum, tantalum, nickel, iron, silicon, molybdenum, a carbide, transition metals, or a combination of two or more thereof. The bonding layers 150, 160 may have a lower thermal conductivity than the thermal spreader layer 140. In some embodiments, the bonding layers 150, 160 have a same or substantially similar thermal conductivity as the first and second encapsulating layers 102, 104. In some other embodiments, the bonding layers 150, 160 have a higher thermal conductivity than the first and second substrates 120, 130.

In some embodiments, the bonding layers 150, 160 may be formed on the substrates 120, 130 by foil, plating, thermal spray coating, sputter coating, or other deposition processes (e.g., CVD, PVD, PE-CVD, ALD, etc.), for example. In some other embodiments, the bonding layers 150, 160 are formed directly on the substrates 120, 130; while in some other embodiments, the bonding layers 150, 160 are formed on the thermal spreader layer 140. In some embodiments, the bonding layers 150, 160 have a thickness between approximately 1 micron and 50 microns, approximately 5 microns and 10 microns, approximately 5 microns to 25 microns, approximately 1 and 750 microns, between approximately 2 and 500 microns, or greater than 1 microns, for example. When the thickness of the bonding layers 150, 160 is between, for example, approximately 5 microns and 50 microns, the bonding layers 150, 160 may enable a strong metal-to-metal bond through carbon diffusion between the substrates 120, 130 and respective bonding layers 150, 160 without significantly lowering the mechanical strength of the bond. When carbon diffuses into the bonding layers 150, 160 and/or material of the bonding layers 150, 160 diffuses into the substrates or thermal spreader layers 120, 130, 140, bonding between said layers is improved.

The carbon diffusion into the bonding layers 150, 160 often stops between about 5 and 50 microns. In some such embodiments, the carbon diffusion barrier effect of the bonding layers 150, 160 does not change once the thickness is greater than about 5 to 50 microns. For example, in some embodiments, when the bonding layers 150, 160 include nickel, the bonding layers 150, 160 have a thickness of about 5 to 10 microns; when the bonding layers 150, 160 include chromium, the bonding layers 150, 160 have a thickness of about 10 to 25 microns; and when the bonding layers 150, 160 include molybdenum, the bonding layers 150, 160 have a thickness of about 25 to 50 microns. In some embodiments, when the bonding layers 150, 160 each include chromium having a thickness of between about 10 and 25 microns, carbon diffusion is blocked, sufficient diffusion bonding of the substrates 120, 130, can occur, and the bonding layers 150, 160 is not fully consumed.

In embodiments where support vias 180 are present (e.g., FIG. 5A), at least one of the bonding layers 150, 160 may be on the substrates 120, 130 but around the vias 180. In some embodiments, the bonding layers 150, 160 are formed on the respective substrates 120, 130 via a diffusion process. Masking may be used to prevent the formation of the bonding layers 150, 160 on certain areas of the respective substrates 120, 130, such as on the periphery of the substrates 120, 130 that will later be bonded to one another or on various surfaces of support vias 180, if present.

The thermal leveler 100 may be formed by any suitable method for attaching the substrates 120, 130 to the thermal spreader layer 140. In one embodiment, thermal leveler 100 may be formed by arranging the various thermally conductive pieces 140a, 140b on a bonding layer (e.g., 150, 160) and/or substrates (e.g., 120, 130) to form the thermal spreader layer 140, aligning the metal substrates 120, 130 with the thermal spreader layer 140, and bonding the substrates 120, 130 to opposing surfaces of the thermal spreader layer 140. In some embodiments, the bonding is performed via lamination such that the substrates 120, 130 are positioned adjacent to the respective surfaces of the thermal spreader layer 140, and the structure is passed through rollers to laminate the substrates 120, 130 to the respective surfaces of the thermal spreader layer 140.

In some embodiments where there are bonding layers 150, 160 such as in FIG. 3A, the bonding layers 150, 160 may be provided on the surfaces of the thermal spreader layer 140 to adhere the various pieces 140a, 140b of the thermal spreader layer 140 to one another. Then, the thermal spreader layer 140 comprising the first and/or second bonding layers 150, 160 may be aligned and arranged between the substrates 120, 130 for bonding. In some embodiments, the thermal spreader layer 140 and first and/or second bonding layers 150, 160 are trimmed to a desired final dimension before being placed between the substrates 120, 130. In some embodiments, the bonding layers 150, 160 are provided in discrete areas on the surface or may be applied generally to an entire surface of the thermal spreader layer 140. It will be appreciated that a curing or activation operation may be required to set or cure the bonding layer(s) 150, 160. In one embodiment, the bonding layers 150, 160 may include a thermally conductive epoxy, braze, solder, or other similar material. A heating step may then be performed to activate the bonding layer(s) 150, 160 to the thermal spreader layer 140.

In some other embodiments, the bonding layers 150, 160 may first be arranged on the respective substrates 120, 130. Then, the pieces of the thermal spreader layer 140 are arranged on one of the substrates 120, 130. When the bonding layers 150, 160 are present, the thermal spreader layer 140 may be assembled directly on one of the bonding layers 150, 160 on the respective substrate 120, 130. In some embodiments, the bonding layers 150, 160 are formed on parts or the entirety of the substrates 120, 130 by, for example, foil, plating, thermal spray coating, sputter coating, or other deposition processes (e.g., CVD, PVD, PE-CVD, ALD, etc.).

In some embodiments, at least one of the substrates 120, 130 includes a cavity configured to receive the thermally conductive pieces 140a, 140b. The cavity may assist with aligning the thermally conductive pieces 140a, 140b within a desired area on the substrate 120, 130 and reduce damage to the thermally conductive pieces 140a, 140b.

Once the substrates 120, 130, the thermal spreader layer 140, and optional bonding layers 150, 160 are aligned with one another to form a stack, a final bonding process is performed to bond the first substrate 120 to the second substrate 130 and secure the thermal spreader layer 140 between the substrates 120, 130. In some embodiments, a thermally conductive epoxy, braze, solder, or other similar material is applied to the joining surfaces of the substrates 120, 130, the thermal spreader layer 140, and/or the bonding layers 150, 160. Then, when the joining surfaces are brought together, the assembly may be brought to an activation temperature to effectively bond the assembly at the joining surfaces. In another embodiment, no bonding material is applied and the bonding between the substrates 120, 130 is performed under high temperature and high pressure via diffusion bonding.

When the thermal leveler 100 includes vias, such as the vias 180 illustrated in FIG. 5A, the vias 180 may also bond to the substrates 120, 130 and/or the thermal spreader layer 140 via a bonding substance, a lamination process, or diffusion bonding. In an embodiment employing vias 180, holes are predrilled into the thermally conductive pieces 140a, 140b at a desired size and spacing to match vias 180 connecting the substrates 120, 130 to produce optimized results. Thermally conductive epoxy, braze, solder, or any other similar material may be applied to the surface of the thermal spreader layer 140 and/or the surface of the substrates 120, 130 and may be used to join the substrates 120, 130 either partially or completely. The loading density of the vias 180 may be selected as desired for a particular purpose or intended application. In one embodiment, the via loading density would be present from less than 0.01% of the thermal spreader area to approximately 40% thermal spreader area. The thermal spreader area is the total surface area of the thermal spreader layer 140 if no holes were present in the thermal spreader layer 140 to accommodate for vias 180. For example, if the thermal spreader layer 140 is a disc-like structure, the thermal spreader area would be based on the radius of the disc; any holes present throughout the disc to accommodate for vias 180 would not be subtracted from the thermal spreader area calculation. In another embodiment the via loading density may be from about 0.1% to about 20% of the thermal spreader area. In one embodiment, the spacing of the vias may range from about 0.5 to about 125 mm. In another embodiment, the spacing of the vias may range from about 1 to about 25 mm.

In an embodiment employing vias 180, the vias 180 may be connected to or part of the substrates 120, 130. The vias 180 may also be a “button” of material that is inserted to rest in between a recess in the first and/or second substrates 120, 130. In one embodiment, the vias 180 are the same material as the substrates 120, 130. The vias 180 may, but are not limited to, have a geometry that is cylindrical, square, tapered, or double-tapered or any shape that may help with mechanical strength, bondability, and/or thermal uniformity.

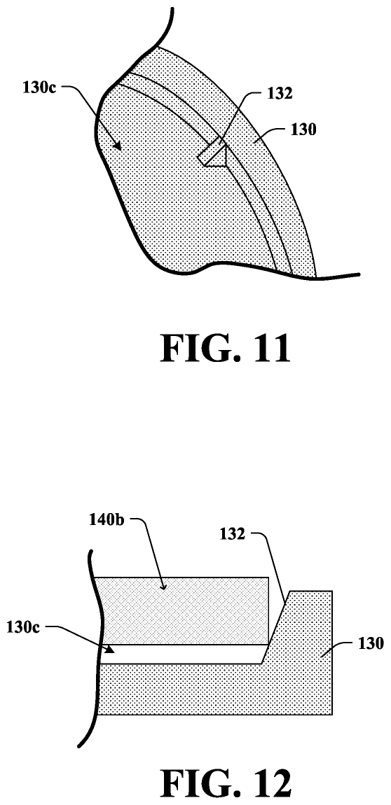

Turning additionally to FIGS. 11 and 12, in some embodiments, at least one of the substrates (e.g., the second substrate 130) may be configured to promote positioning the thermally conductive pieces 140a, 140b in close proximity to one another. For example, in one embodiment, the second substrate 130 includes a cavity 130c and a projection 132 angled toward the lower surface of the second substrate 130 defined by the cavity 130c. The cavity 130c is surrounded by a rim of the second substrate 130, the rim of the second substrate 130 having a topmost surface above the cavity 130c. The thermally conductive pieces 140a, 140b may have an interference fit with the projections 132 of the second substrate 130. As the first substrate 120 is placed over the second substrate 130 for bonding, the thermally conductive pieces 140a, 140b may be pushed down and inward to move the angled edges 142a, 142b of the pieces 140a, 140b toward one another. In other embodiments, the substrates 120, 130 may include some other positioning structures (e.g., protrusions, recesses, vias, notches, etc.) configured to assist with aligning the various pieces 140a, 140b of the thermal spreader layer 140 with one another and between the substrates 120, 130.

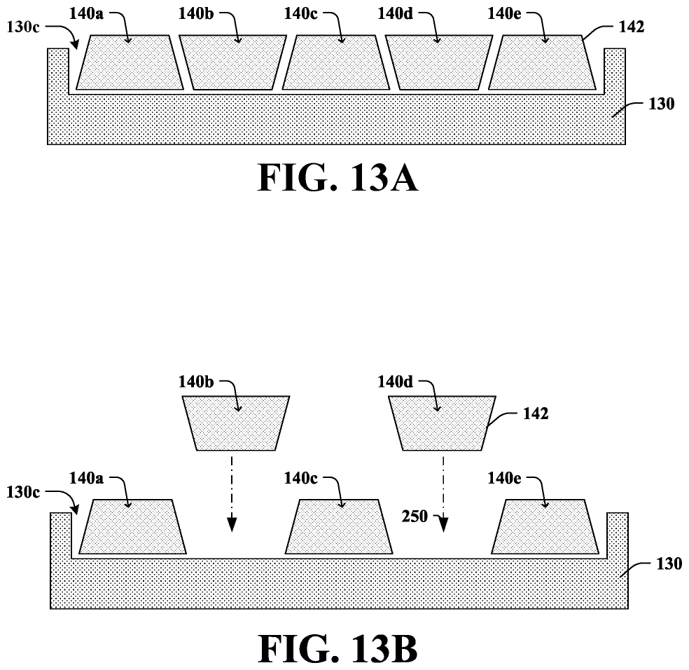

Turning additionally to FIG. 13A, a cross-sectional view of some other embodiments of the thermal spreader layer 140 arranged within a cavity 130c of the second substrate 130 is illustrated. The thermal spreader layer 140 may include a first thermally conductive piece 140a, a second thermally conductive piece 140b, a third thermally conductive piece 140c, a fourth thermally conductive piece 140d, and a fifth thermally conductive piece 140e. Each piece 140a-e may include beveled edges 142. It will be appreciated that other edge profiles may be used as described above.

In some embodiments, the pieces 140a-e are arranged manually over the substrate 130, while in other embodiments, the pieces 140a-e are arranged over the substrate 130 using assistive technology such as a robot arm. As previously discussed, the pieces 140a-e may be arranged on a bonding layer (e.g., 150 or 160 of FIG. 3A) and/or over a substrate 130. In some embodiments, the pieces 140a-e may be arranged from one direction towards another direction, such that adjacent pieces 140a-e are sequentially placed. For example, in FIG. 13A, the first piece 140a may be placed, followed by the second piece 140b, followed by the third piece 140c, followed by the fourth piece 140d, followed by the fifth piece 140e.

Turning additionally to FIG. 13B, in some other embodiments, a first set of pieces may be aligned over the substrate 130 followed by a second set of pieces. For example, in FIG. 13B, at least because each piece 140a-140e is substantially symmetrical with one another along a vertical axis, the first, third, and fifth pieces 140a, 140c, 140e may first be placed over the substrate 130. Then, as indicated by arrows 250, the second and fourth pieces 140b, 140d are placed in the spaces between the first, third, and fifth pieces 140a, 140c, 140e.

The following examples are provided to illustrate the various aspects and advantages but should not be construed as limiting the scope of the claimed subject matter.

### Example 1

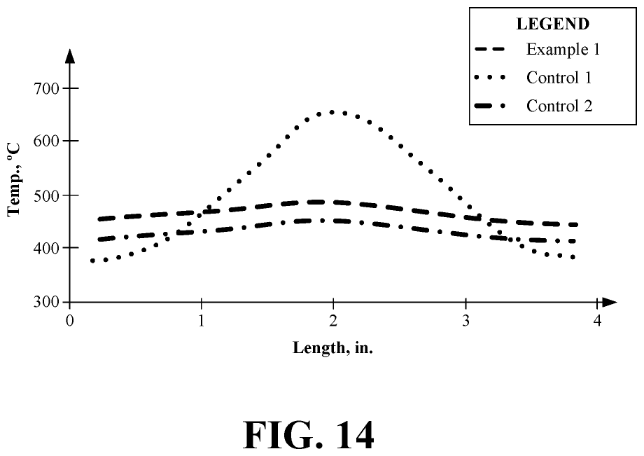

FIG. 14 illustrates temperature profiles of an assembly throughout a length (or diameter) of the assembly. The data in FIG. 14 revealed that the temperature profile of a thermal leveler is significantly more uniform across a length of the thermal leveler when the thermal leveler includes a thermal spreader layer having thermally conductive pieces in close contact with one another along adjacent edges having a 45-degree chamfer (Example 1) compared to a single, metal blank with no thermal spreader layer (Control 1). Additionally, when compared to a thermal leveler with a single piece of a thermal spreader layer (Control 2), Example 1 had a comparable temperature profile that is substantially uniform.

In particular, Example 1 was prepared by encapsulating two pieces of thermal pyrolytic graphite in a 4″ diameter stainless steel (316L SS) disk heat spreader. Edges of the mating thermal pyrolytic graphite pieces had a 45 degree chamfer for enhanced interfacing with each other. The mating thermal pyrolytic graphite pieces were arranged in close contact with one another. The sample used for Example 1 in this instance was bonded via active brazing. Similar results have been obtained when using diffusion bonding.

The thermal spreading profile data of FIG. 14 was collected on Example 1 and on two controls. Control 1 was a stainless steel blank with no thermal spreader layer. Control 2 was a thermal leveler with a single piece of thermal spreader layer encapsulated in stainless steel. The thermal spreading profile was evaluated by placing a thermal leveler or blank over a heater of smaller diameter centrally positioned below the thermal leveler. An infrared radiation camera was placed above the thermal leveler to measure the temperature of the thermal leveler throughout the length (or diameter) of the thermal leveler.

As shown in FIG. 14, the thermal leveler of Example 1 has a much more uniform temperature profile than Control 1, indicating that the presence of thermal pyrolytic graphite in the thermal leveler does improve thermal spreading. Additionally, as shown in FIG. 14, the thermal leveler of Example 1 has a comparable temperature profile compared to the Control 2, indicating that the arrangement of thermally conductive pieces in Example 1 provides a same or similar effect as using a single piece of thermal spreader layer. Thus, a thermal spreader layer having multiple pieces overlapped with one another can be used in large applications where producing a single piece of thermal spreader may be impractical due to the manufacturing limitations of the thermal spreader layer.

The data in FIG. 14 was also collected when Example 1 and Control 2 were formed using a diffusion bonding process (without any braze material). Identical results were obtained.

### Example 2

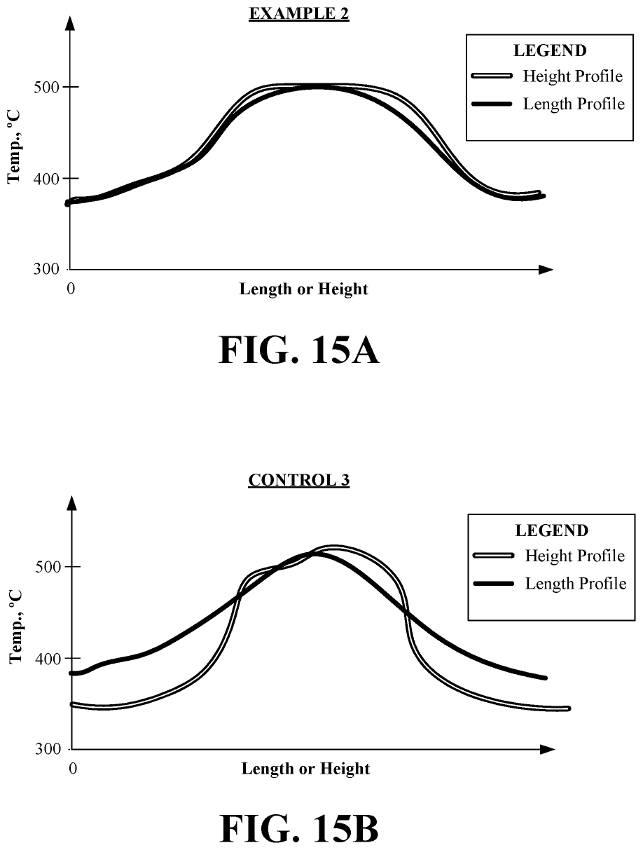

FIGS. 15A and 15B illustrate temperature profiles of an assembly throughout a length (or diameter) of the assembly and throughout a height (or thickness) of the assembly. The data in FIGS. 15A and 15B reveal that the temperature profile of a thermal leveler is significantly more uniform along the length and thickness of the thermal leveler when the thermal leveler includes a thermal spreader layer having thermally conductive pieces in close contact with one another along adjacent edges having a 45-degree chamfer (Example 2 in FIG. 15A) compared a thermal leveler including a thermal spreader layer having thermally conductive pieces that do not overlap one another (Control 3 in FIG. 15B).

In particular, Example 2 was prepared encapsulating two pieces of thermal pyrolytic graphite in an 8.25″ diameter stainless steel (316L SS) disk heat spreader. Edges of the mating thermal pyrolytic graphite pieces had a 45 degree chamfer for enhanced interfacing with each other. The mating thermal pyrolytic graphite pieces were arranged in close contact with one another. The sample used for Example 2 in this instance was bonded via diffusion bonding. Control 3 was provided with multiple pieces of thermal pyrolytic graphite, where adjacent pieces of thermal pyrolytic graphite are spaced apart from one another via a thin layer of stainless steel webbing. No part of the adjacent thermal pyrolytic graphite pieces directly overlapped with one another in the vertical direction.

The data in FIGS. 15A and 15B was collected using the same testing method described with respect to the data in FIG. 14. Additionally, to collect the data of FIGS. 15A and 15B, an infrared radiation camera was placed above the thermal leveler to measure the temperature of the thermal leveler along a linear distance as selected by a linear region of interest in the thermal camera software. The sample was heated from below by a 2″×2″ heater positioned below the central region. The data in FIG. 15A corresponds to Example 2, whereas the data in FIG. 15B corresponds to Control 3.

As shown in FIG. 15A, when the thermal pyrolytic graphite pieces are in close contact with one another and at least partially overlap one another in the vertical direction, the associated thermal leveler has a more uniform temperature profile when measured throughout a length and height of the thermal leveler when compared to FIG. 15B.

As shown in FIG. 15B, when the line profile is across the webbing of stainless steel (height profile), the associated thermal leveler shows regional temperature uniformity above the heater (center zone), isolated from the outer zones.

The aforementioned systems, components, (e.g., thermal spreader layers, support vias, bonding layers, among others), and the like have been described with respect to interaction between several components and/or elements. It should be appreciated that such devices and elements can include those elements or sub-elements specified therein, some of the specified elements or sub-elements, and/or additional elements. Further yet, one or more elements and/or sub-elements may be combined into a single component to provide aggregate functionality. The elements may also interact with one or more other elements not specifically described herein.

While the embodiments discussed herein have been related to the apparatus, systems and methods discussed above, these embodiments are intended to be exemplary and are not intended to limit the applicability of these embodiments to only those discussions set forth herein.

The above examples are merely illustrative of several possible embodiments of various aspects of the present invention, wherein equivalent alterations and/or modifications will occur to others skilled in the art upon reading and understanding this specification and the annexed drawings. In particular regard to the various functions performed by the above described components (assemblies, devices, systems, circuits, and the like), the terms (including a reference to a “means”) used to describe such components are intended to correspond, unless otherwise indicated, to any component, such as hardware, software, or combinations thereof, which performs the specified function of the described component (e.g., that is functionally equivalent), even though not structurally equivalent to the disclosed structure which performs the function in the illustrated implementations of the invention. In addition, although a particular feature of the invention may have been disclosed with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising.”

This written description uses examples to disclose the invention, including the best mode, and also to enable one of ordinary skill in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that are not different from the literal language of the claims, or if they include equivalent structural elements with insubstantial differences from the literal language of the claims.

In the specification and claims, reference will be made to a number of terms that have the following meanings. The singular forms “a”, “an” and “the” include plural referents unless the context clearly dictates otherwise. Approximating language, as used herein throughout the specification and claims, may be applied to modify a quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Moreover, unless specifically stated otherwise, a use of the terms “first,” “second,” etc., do not denote an order or importance, but rather the terms “first,” “second,” etc., are used to distinguish one element from another.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur—this distinction is captured by the terms “may” and “may be.”

The best mode for carrying out the invention has been described for purposes of illustrating the best mode known to the applicant at the time and enable one of ordinary skill in the art to practice the invention, including making and using devices or systems and performing incorporated methods. The examples are illustrative only and not meant to limit the invention, as measured by the scope and merit of the claims. The invention has been described with reference to preferred and alternate embodiments. Obviously, modifications and alterations will occur to others upon the reading and understanding of the specification. It is intended to include all such modifications and alterations insofar as they come within the scope of the appended claims or the equivalents thereof. The patentable scope of the invention is defined by the claims, and may include other examples that occur to one of ordinary skill in the art. Such other examples are intended to be within the scope of the claims if they have structural elements that do not differentiate from the literal language of the claims, or if they include equivalent structural elements with insubstantial differences from the literal language of the claims.

What is claimed is:

1. A thermal management device comprising:
a first substrate;
a second substrate arranged over the first substrate; and
a thermal spreader layer arranged between the first substrate and the second substrate, the thermal spreader layer having a first thermally conductive piece having a first edge and a second thermally conductive piece having a first edge, wherein the first edge of the first thermally conductive piece is disposed adjacent the first edge of the second thermally conductive piece.

2. The thermal management device of claim 1, wherein the first edge of the first thermally conductive piece and the first edge of the second thermally conductive piece directly overlap one another in a direction normal to a thickness of the first and second thermally conductive pieces.

3. The thermal management device of claim 1, wherein the first edge of the first thermally conductive piece is beveled at an angle α, and the first edge of the second thermally conductive piece is beveled at an angle β, and the angles α and β are each independently greater than 0° and less than 90° relative to vertical.

4. The thermal management device of claim 3, wherein the angles α and β are complimentary angles to one another having a sum of 90°.

5. The thermal management device of claim 1, wherein the first edge of the first thermally conductive piece is in direct contact with the first edge of the second thermally conductive piece.

6. The thermal management device of claim 1, further comprising a machined feature or insert of substrate material is positioned as a thermal dam between different regions of continuous thermally conductive pieces.

7. The thermal management device of claim 1, wherein the first edge of the first thermally conductive piece is spaced apart from the first edge of the second thermally conductive piece by a gap.

8. The thermal management device of claim 7, wherein the gap is from about 0.001″ to about 0.100″.

9. The thermal management device of claim 1, wherein the first edge of the first thermally conductive piece and the first edge of the second thermally conductive piece are ship lapped.

10. The thermal management device of claim 1, wherein the first substrate contains a via protruding from the first substrate and extending through the thermal spreader layer.

11. The thermal management device of claim 10, wherein the via extends through both the first thermally conductive piece and the second thermally conductive piece.

12. The thermal management device of claim 10, wherein the second substrate includes a recess configured to receive and mate with the via from the first substrate.

13. The thermal management device of claim 1, wherein the thermal spreader layer includes separate thermally conductive material arranged in at least two separate zones, wherein the first thermally conductive piece and the second thermally conductive piece form a part of respective zones or form a part of one zone.

14. A thermal management device comprising:
a first substrate;
a second substrate arranged over the first substrate; and
a thermal spreader layer stacked between the first substrate and the second substrate, the thermal spreader layer having a first thermally conductive piece having a first edge and a second thermally conductive piece having a first edge, wherein the first edge of the first thermally conductive piece directly overlaps the first edge of the second thermally conductive piece.

15. The thermal management device of claim 14, wherein the thermal spreader layer has a thermal conductivity that is greater than each thermal conductivity of each of the first and second substrates.

16. The thermal management device of claim 14, wherein the thermal spreader layer includes at least one of thermal pyrolytic graphite or diamond.

17. The thermal management device of claim 14, wherein the thermal management dimension has a dimension that exceeds the viable manufacturable dimension of the thermal spreader layer, requiring a tiling strategy to maintain continuous thermal spreading.

18. The thermal management device of claim 14, further comprising a first bonding layer arranged between the thermal spreader layer and the first substrate; and a second bonding barrier layer arranged between the thermal spreader layer and the second substrate.

19. A method of making a thermal management device comprising:
providing a first substrate having a cavity;
disposing a first thermally conductive piece having a first edge within the cavity of the first substrate;
disposing a second thermally conductive piece having a first edge within the cavity, wherein the first edge of the second thermally conductive piece is positioned adjacent the first edge of the first thermally conductive piece;
arranging a second substrate over the first and second thermally conductive pieces and the first substrate to encapsulate the first and second thermally conductive pieces; and
bonding the first substrate to the second substrate.

20. The method of claim 19, wherein the cavity is defined by a perimeter wall and a lower surface of the first substrate, wherein the first substrate includes one or more projections extending from the perimeter wall and angled toward the lower surface of the first substrate,
wherein the first thermally conductive piece and the second thermally conductive piece are positioned on the projections, and when the second substrate is arranged over and bonded to the first substrate, pressure is applied to the first and second thermally conductive pieces such that the projections push the first edge of the first thermally conductive piece and the first edge of the second thermally conductive piece toward each other, and,
wherein the first edge of the first thermally conductive piece and the first edge of the second thermally conductive piece are pushed into contact with one another.
